(19) United States
(12) Patent Application Publication
(10) Pub. No.: US 2022/0267143 A1
(43) Pub. Date: Aug. 25, 2022

(54) MICROELECTROMECHANICAL HEATING DEVICE

(71) Applicant: INDUSTRIAL TECHNOLOGY RESEARCH INSTITUTE, Hsinchu (TW)

(72) Inventors: Ming-Fa CHEN, Taoyuan City (TW); Bor-Shiun LEE, New Taipei City (TW)

(73) Assignee: INDUSTRIAL TECHNOLOGY RESEARCH INSTITUTE, Hsinch (TW)

(21) Appl. No.: 17/372,055

(22) Filed: Jul. 9, 2021

(30) Foreign Application Priority Data
Feb. 19, 2021 (TW) 110105603

(51) Int. Cl. B81B 7/00; H05B 3/26

(52) U.S. Cl. CPC B81B 7/0096; H05B 3/26; H05B 2203/003; B81B 7/0087; B81B 2201/0292

(57) ABSTRACT

A microelectromechanical heating device includes a substrate, a thermal insulator, and a heater. The thermal insulator includes a plurality of supporting structures and at least one thermal insulation layer. The supporting structures are disposed on the substrate. The thermal insulation layer is located above the substrate and connected to the plurality of supporting structures. The thermal insulation layer is spaced apart from the substrate by a distance. The heater is disposed on the at least one thermal insulation layer.

### CROSS-REFERENCE TO RELATED APPLICATIONS

This non-provisional application claims priority under 35 U.S.C. § 119(a) on Patent Application No(s). 110105603 filed in Taiwan (R.O.C.) on Feb. 19, 2021, the entire contents of which are hereby incorporated by reference.

### TECHNICAL FIELD

The disclosure relates to a heating device, more particularly a microelectromechanical heating device.

### BACKGROUND

A MEMS (micro-electro-mechanical system) sensor and its environment need to be preheated to a specific working temperature before the sensing operation in order to obtain a precise and accurate measurement. For this matter, a typical MEMS sensor generally contains a heater for heating itself.

However, the heater of the conventional MEMS sensors is inefficient and power-consuming due to excessive heat loss, leading to an unstable working temperature for the sensor and thereby affecting the sensing accuracy and precision.

### SUMMARY

One embodiment of the disclosure provides a microelectromechanical heating device including a substrate, a thermal insulator, and a heater. The thermal insulator includes a plurality of supporting structures and at least one thermal insulation layer. The supporting structures are disposed on the substrate. The thermal insulation layer is located above the substrate and connected to the plurality of supporting structures. The thermal insulation layer is spaced apart from the substrate by a distance. The heater is disposed on the at least one thermal insulation layer.

According to the microelectromechanical heating device as discussed in the above embodiment of the disclosure, the heater is disposed on a substrate that is spaced apart from the thermal insulation layer, such that the thermal energy generated by the heater is not easily conducted to the substrate. Thus, the heat loss of through the substrate is significantly reduced and prevented so that the heater is able to achieve the predetermined working temperature in an effective and efficient manner, and the heater is easily to maintain the predetermined working temperature.

### BRIEF DESCRIPTION OF THE DRAWINGS

FIG. 1 is a perspective view of a microelectromechanical heating device according to one embodiment of the disclosure;

FIG. 2 is a cross-sectional side view of the microelectromechanical heating device taken along line 2-2 in FIG. 1;

FIG. 3 is an exploded view of the microelectromechanical heating device in FIG. 1;

FIG. 4 is a partial perspective view of the microelectromechanical heating device in FIG. 1;

FIG. 5 is a cross-sectional view of the microelectromechanical heating device taken along line 5-5 in FIG. 4;

FIG. 6 is a partial perspective view of the microelectromechanical heating device in FIG. 1;

FIG. 7 is a cross-sectional view of the microelectromechanical heating device taken along line 7-7 in FIG. 6;

FIG. 8 is a partial perspective view of the microelectromechanical heating device in FIG. 1;

FIG. 9 is a cross-sectional view of the microelectromechanical heating device taken along line 9-9 in FIG. 8;

FIG. 10 is a partial perspective view of the microelectromechanical heating device in FIG. 1;

FIG. 11 is a cross-sectional view of the microelectromechanical heating device taken along line 11-11 in FIG. 10;

FIG. 12 is a partial perspective view of the microelectromechanical heating device in FIG. 1;

FIG. 13 is a cross-sectional view of the microelectromechanical heating device taken along line 13-13 in FIG. 12;

FIG. 14 is a partial perspective view of the microelectromechanical heating device in FIG. 1;

FIG. 15 is an exploded view of an application that adapts the microelectromechanical heating device in FIG. 1;

FIG. 16 is a perspective view of the application that adapts the microelectromechanical heating device in FIG. 15;

FIG. 17 is a perspective view of a microelectromechanical heating device according to another embodiment of the disclosure;

FIG. 18 is a cross-sectional side view of the microelectromechanical heating device taken along line 18-18 in FIG. 17;

FIG. 19 is a cross-sectional side view of a microelectromechanical heating device according to another embodiment of the disclosure;

FIG. 20 is a perspective view of a microelectromechanical heating device according to another embodiment of the disclosure; and

FIG. 21 is a cross-sectional side view of the microelectromechanical heating device taken along line 21-21 in FIG. 20.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details.

The following embodiments will be described with reference to the drawings. For the purpose of clear illustration, some conventional elements and components may be illustrated in a simple and clear manner. Some of the features in the drawings may be slightly exaggerated or illustrated in a larger proportion for the ease of viewing but are not intended to limit the disclosure. In addition, for the same reason, some of the elements or components in the drawings may be illustrated in dotted lines.

Herein, the terms, such as “end”, “part”, “portion”, “area”, may be used to refer to specific features of or between elements or components but are not intended to limit the elements and components. Further, unless explicitly stated, the term “at least one” as used herein may mean that the quantity of the described element or component is one or larger than one but does not necessarily mean that the quantity is only one.

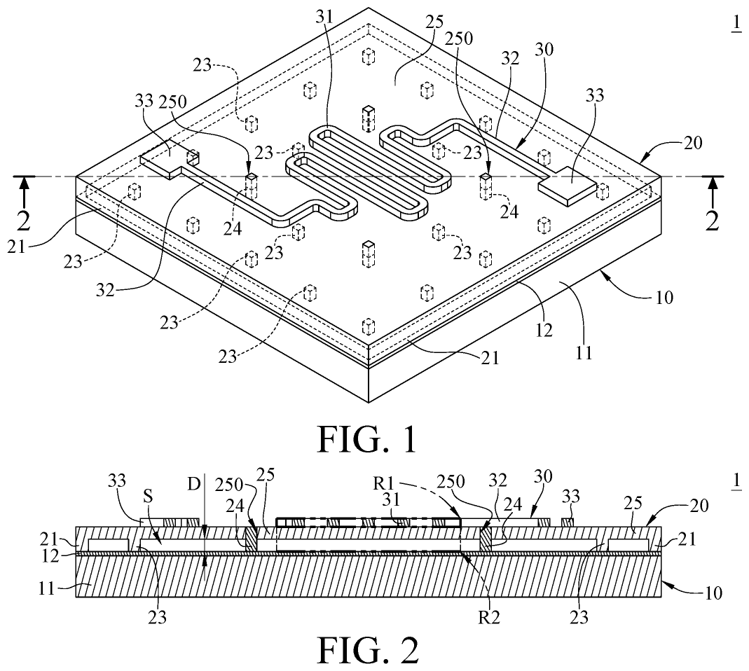

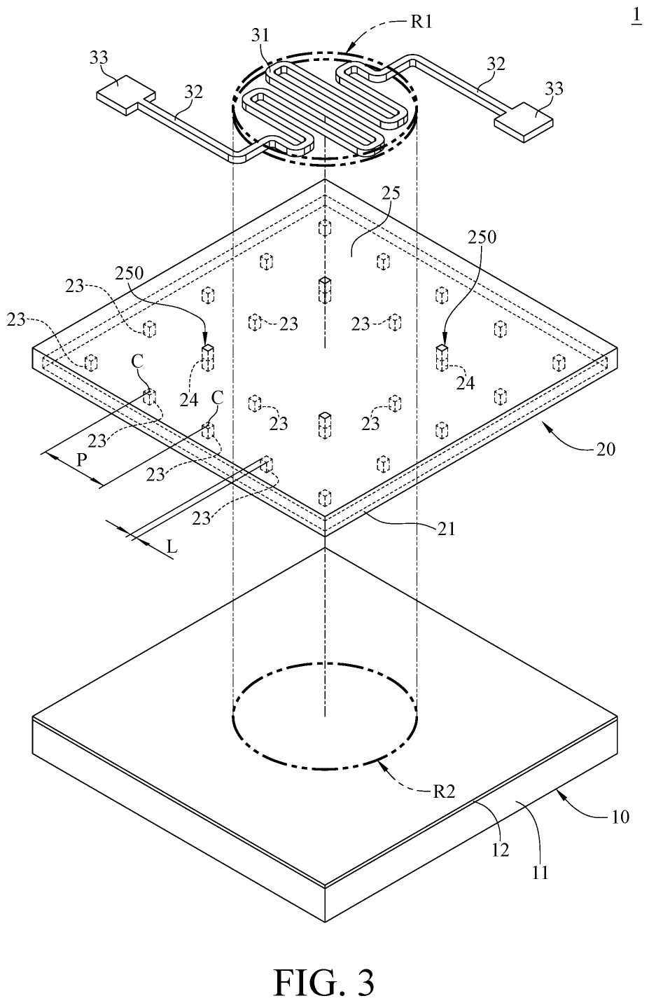

Referring to FIGS. 1-3, where FIG. 1 is a perspective view of a microelectromechanical heating device according to one embodiment of the disclosure, FIG. 2 is a cross-sectional side view of the microelectromechanical heating device taken along line 2-2 in FIG. 1, and FIG. 3 is an exploded view of the microelectromechanical heating device in FIG. 1.

As shown in FIGS. 1 and 2, in this embodiment, the microelectromechanical heating device 1 includes a substrate 10, a thermal insulator 20, and a heater 30. The thermal insulator 20 is disposed on the substrate 10. The heater 30 is disposed on the thermal insulator 20.

The substrate 10 includes a non-electrically insulating layer 11 and an electrically insulating layer 12 which are stacked on each other. The non-electrically insulating layer 11 may be made of electrically conductive or semiconductive material, and the electrically insulating layer 12 may be made of made of electrically insulating material, but the disclosure is not limited thereto. In other embodiments, the substrate 10 may only include the electrically insulating layer 12; in other words, the substrate 10 may omit the non-electrically insulating layer 11.

As shown in FIGS. 2 and 3, in this embodiment, the thermal insulator 20 includes a sidewall structure 21, a plurality of first supporting structures 23, a plurality of second supporting structures 24, and a thermal insulation layer 25. The sidewall structure 21, the first supporting structures 23 and the second supporting structures 24 are disposed above the electrically insulating layer 12 of the substrate 10. The thermal insulation layer 25 is disposed above the electrically insulating layer 12 of the substrate 10 and is connected to the sidewall structure 21, the first supporting structures 23, and the second supporting structures 24. The electrically insulating layer 12 is located closer to the thermal insulation layer 25 than the non-electrically insulating layer 11. The thermal insulation layer 25 and the electrically insulating layer 12 of the substrate 10 are spaced apart by a distance D, such that there is a space S between the thermal insulation layer 25 and the electrically insulating layer 12 of the substrate 10. In this embodiment, the distance D between the thermal insulation layer 25 and the electrically insulating layer 12 of the substrate 10 is greater than or equal to 0.2 micrometers, but the disclosure is not limited thereto.

In this embodiment, the heater 30 is disposed on the thermal insulation layer 25. The heater 30 includes a heating portion 31, two wire portions 32, and two electrode portions 33. The heating portion 31 is located within an area Rl. The heating portion 31 may be an electrically heated wire in a serpentine or meander shape. The wire portions 32 are respectively connected to two ends of the heating portion 31 and are electrically connected to the heating portion 31. The electrode portions 33 are respectively electrically connected to the wire portions 32. When a power source (not shown) provides electrical energy to the electrode portions 33, the heating portion 31 converts electrical energy to thermal energy so that the temperature of the heating portion 31 is increased. As shown, an area R2 denotes an orthogonal projection of the area R1 of the heating portion 31 projecting onto the electrically insulating layer 12 of the substrate 10.

In this embodiment, there is only one sidewall structure 21 on the thermal insulator 20. The sidewall structure 21 is disposed on the electrically insulating layer 12 of the substrate 10. The sidewall structure 21 is located between the thermal insulation layer 25 and the electrically insulating layer 12 of the substrate 10. The sidewall structure 21 may be in a circular, quadrilateral, or any shape that is suitable for surrounding the area R2. In this embodiment, the sidewall structure 21 is in a square shape, but the disclosure is not limited thereto. In other embodiments, the shape of the sidewall structure 21 may be modified as required.

In this embodiment, the thermal insulator 20 comprises a plurality of first supporting structures 23. The first supporting structures 23 are arranged in an array on the electrically insulating layer 12 of the substrate 10, and a part of the first supporting structures 23 are arranged to avoid overlapping the area R2. The first supporting structures 23 are located between the thermal insulation layer 25 and the electrically insulating layer 12 of the substrate 10. Each of the first supporting structures 23 is a column-shaped object having a square cross-section. Each of the first supporting structures 23 has a central axis C and a width L. The width L is a cross-section width of each the first supporting structure 23. Two of the central axes C that are located adjacent to each other are spaced apart by a distance P. The distance P divided by the width L is greater than or equal to 15.3, but the disclosure is not limited thereto. In other embodiments, each of the first supporting structures 23 may be a column having a square, a circular, oval, oval-like, polygonal, or any other shape cross-section; in other words, each of the first supporting structures 23 may be a circular column, oval column, oval-like column, polygonal column, or any other shaped column. In the case that each of the first supporting structures 23 is a circular column, the width L is the diameter of the cross-section. In the case that each of the first supporting structures 23 is an oval column or an oval-like column, the width L is the average of the long and short axes of the cross-section. In the case that each of the first supporting structures 23 is a polygonal column, the width L is the square root of the cross-section.

In this embodiment, the thermal insulator 20 has a plurality of second supporting structures 24. The second supporting structures 24 are disposed on the electrically insulating layer 12 of the substrate 10 and do not overlap with the area R2. The thermal insulation layer 25 has a plurality of through holes 250, the second supporting structures 24 respectively extend to the through holes 250 of the thermal insulation layer 25 so as to penetrate through the thermal insulation layer 25. As such, the second supporting structures 24 are connected to the thermal insulation layer 25 and seal the through holes 250. Each of the second supporting structures 24 is a column-shaped object having a square cross-section, but the disclosure is not limited thereto. In other embodiments, each of the second supporting structures 24 may be a column having a circular, oval, oval-like, polygonal, or any other shape ross-section; in other words, each of the second supporting structures 24 may be a circular column, oval column, oval-like column, polygonal column, or any other shaped column. In this embodiment, the thermal insulator 20 has four second supporting structures 24, but the disclosure is not limited thereto. In other embodiments, the thermal insulator 20 may have only one second supporting structure 24. In other words, the number of the second supporting structure 24 on the thermal insulator 20 may be modified as required.

The space S formed by the electrically insulating layer 12 of the substrate 10, the sidewall structure 21, the second supporting structures 24, and the thermal insulation layer 25 is an airtight space. In this embodiment, the space S is a vacuum space, but the disclosure is not limited thereto. In other embodiments, the space S may not be a vacuum space.

During the operation of the microelectromechanical heating device 1, the electrode portions 33 of the heater 30 receive electrical energy and therefore raise the temperature of the heating portion 31 through the wire portions 32. The area of the thermal insulation layer 25 that is disposed with the heating portion 31 is spaced apart from the electrically insulating layer 12 of the substrate 10 by a distance D, such that the space S is formed between the thermal insulation layer 25 and the electrically insulating layer 12 of the substrate 10. This increases the thermal resistance between the heating portion 31 and the substrate 10. As such, the thermal energy generated by the heating portion 31 is not easily conducted to the substrate 10. Also, the distance P between adjacent first supporting structures 23 divided by the width L of each first supporting structure 23 is greater than or equal to 15.3, thus the heat conduction area between the thermal insulation layer 25 and the substrate 10 is small to a level that can suppress the temperature increase of the substrate 10 to be less than 50 degrees Celsius while the thermal insulation layer 25 is firmly supported and spaced apart from the electrically insulating layer 12 of the substrate 10.

In addition, since the space S formed by the electrically insulating layer 12 of the substrate 10, the sidewall structure 21, the second supporting structures 24, and the thermal insulation layer 25 is an airtight and vacuum space, there is no convective heat transfer occurring between the thermal insulation layer 25 and the electrically insulating layer 12 of the substrate 10. Thus, the heat loss through the substrate 10 is significantly reduced, such that the heating portion 31 of the heater 30 is able to achieve the predetermined working temperature in an effective and power-saving manner, and it is easy to maintain the predetermined working temperature of the heating portion 31 of the heater 30.

Further, the substrate 10 is not hollowed out and has no physical damage, thus the non-electrically insulating layer 11 of the substrate 10 may have an integrated circuit therein. Therefore, the microelectromechanical heating device 1 and the integrated circuit can be integrated into the same substrate 10.

In another embodiment, the thermal insulator 20 may omit the first supporting structures 23; in such a case, the thermal insulation layer 25 is supported by the sidewall structure 21 and the second supporting structures 24, and so as to form an airtight space S with the substrate 10 to achieve the purpose of thermal insulation.

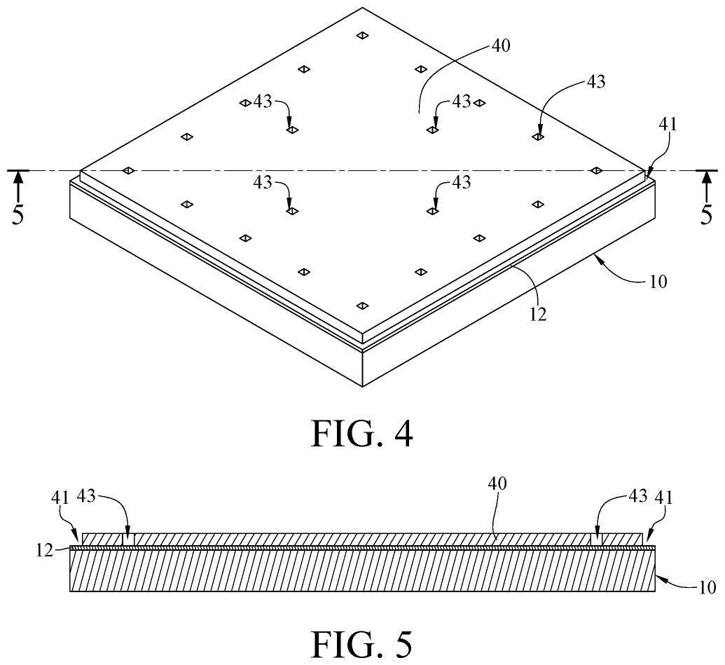

Referring to FIGS. 4-14, the manufacturing processes of the microelectromechanical heating device in FIG. 1 are provided below.

FIG. 4 is a partial perspective view of the microelectromechanical heating device in FIG. 1, and FIG. 5 is a cross-sectional view of the microelectromechanical heating device taken along line 5-5 in FIG. 4. First step is to prepare the substrate 10. In detail, a sacrificial layer 40 is formed on the electrically insulating layer 12 of the substrate 10. Also, the sacrificial layer 40 has a first opening 41 and a plurality of second openings 43 thereon. The electrically insulating layer 12 of the substrate 10 is exposed from the first opening 41 and the second openings 43. The location and shape of the first opening 41 correspond to that of the sidewall structure 21 (ref. FIG. 3). The location and shape of the second openings 43 correspond to that of the first supporting structures 23 (ref. FIG. 3).

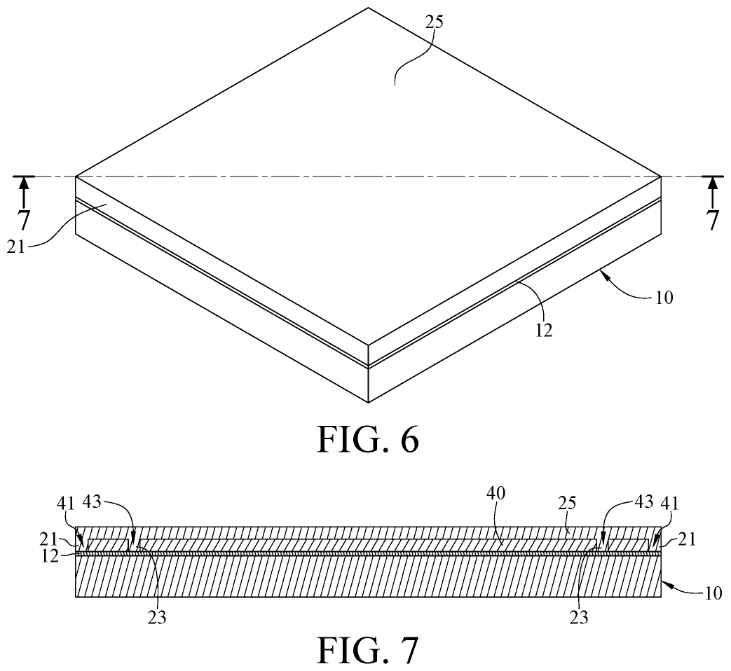

FIG. 6 is a partial perspective view of the microelectromechanical heating device in FIG. 1, and FIG. 7 is a cross-sectional view of the microelectromechanical heating device taken along line 7-7 in FIG. 6. Then, a thermal insulation material is filled into the first opening 41 and the second openings 43 and therefore is attached to the electrically insulating layer 12 of the substrate 10. The thermal insulation material forms the sidewall structure 21 at the first opening 41. The thermal insulation material forms the first supporting structures 23 at the second openings 43. The thermal insulation material forms the thermal insulation layer 25 on the sacrificial layer 40, the sidewall structure 21, and the first supporting structures 23.

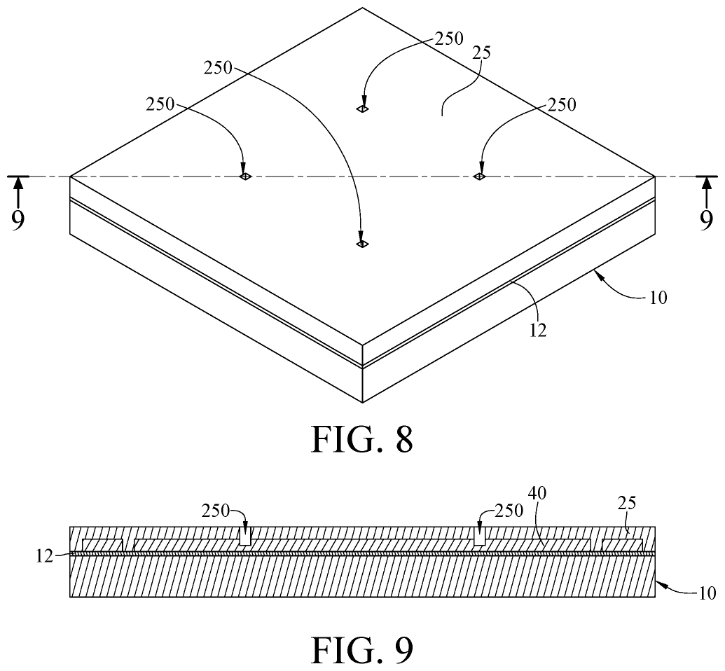

FIG. 8 is a partial perspective view of the microelectromechanical heating device in FIG. 1, and FIG. 9 is a cross-sectional view of the microelectromechanical heating device taken along line 9-9 in FIG. 8. Then, the through holes 250 are formed in the thermal insulation layer 25. The through holes 250 correspond to the locations of the second supporting structures 24 (ref. FIG. 3). The through holes 250 penetrate through the thermal insulation layer 25. At this stage, the part of the sacrificial layer 40 that correspond to the locations of the through holes 250 is removed, but the disclosure is not limited thereto. In other embodiments, the part of the sacrificial layer 40 that correspond to the locations of the through holes 250 may not be removed. In other embodiments, the part of the sacrificial layer 40 that correspond to the locations of the through holes 250 may be removed to expose the surface of the electrically insulating layer 12 of the substrate 10. Then, the part of the sacrificial layer 40 at the through holes 250 of the thermal insulation layer 25 is removed. In this embodiment, the sacrificial layer 40 may be made of volatile material so that the sacrificial layer 40 can be vaporized off when being heated. Thus, the sacrificial layer 40 can be vaporized off from the space S between the thermal insulation layer 25 and the electrically insulating layer 12 of the substrate 10 through the through holes 250, achieving the removal of the sacrificial layer 40, but the disclosure is not limited thereto. In other embodiments, the sacrificial layer 40 may be removed from the through holes 250 by performing other suitable processes, such as dry etching or wet etching.

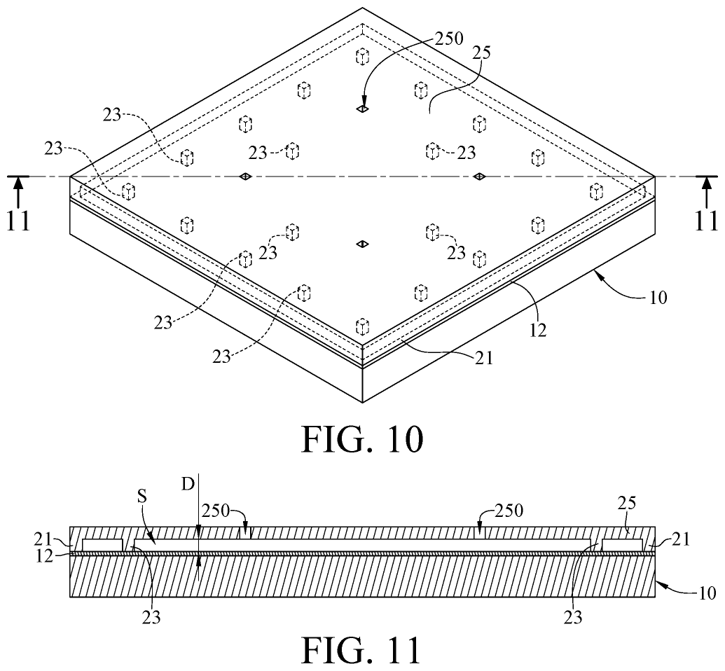

FIG. 10 is a partial perspective view of the microelectromechanical heating device in FIG. 1, and FIG. 11 is a cross-sectional view of the microelectromechanical heating device taken along line 11-11 in FIG. 10. After the removal of the sacrificial layer 40, the sidewall structure 21 and the first supporting structures 23 are disposed on the electrically insulating layer 12 of the substrate 10. The thermal insulation layer 25 is disposed above the electrically insulating layer 12 of the substrate 10 and is connected to the sidewall structure 21 and the first supporting structures 23. The thermal insulation layer 25 and the electrically insulating layer 12 of the substrate 10 are spaced apart by a distance D, such that a space S is formed between the thermal insulation layer 25 and the electrically insulating layer 12 of the substrate 10.

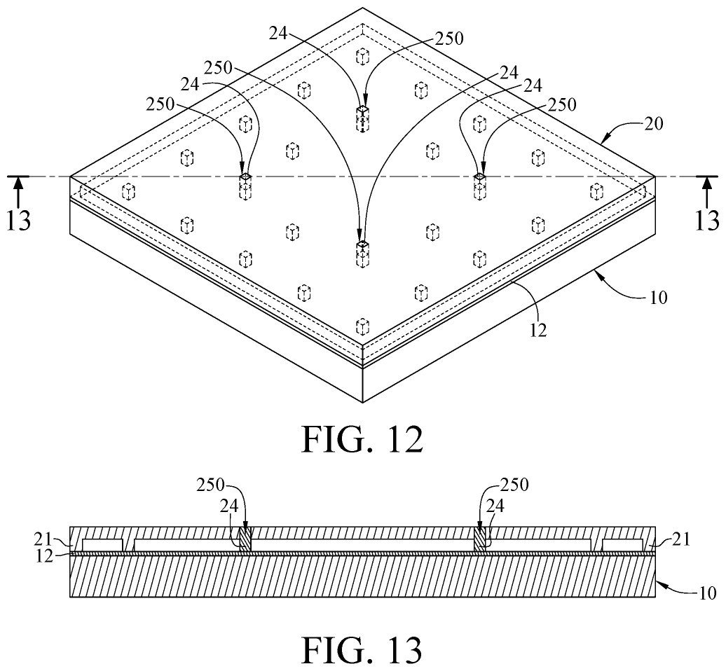

FIG. 12 is a partial perspective view of the microelectromechanical heating device in FIG. 1, and FIG. 13 is a cross-sectional view of the microelectromechanical heating device taken along line 13-13 in FIG. 12. Then, in a vacuum environment, the second supporting structures 24 are formed at the through holes 250 of the thermal insulation layer 25. Through the through holes 250 of the thermal insulation layer 25, the thermal insulation material is deposited on the area that the through holes 250 of the thermal insulation layer 25 orthogonally projects onto the electrically insulating layer 12 of the substrate 10. The through holes 250 are relatively small in size, thus the thermal insulation material is not diffused away from the through holes 250. The thermal insulation material is accumulated within the through holes 250 of the thermal insulation layer 25 so as to seal the through holes 250, thereby forming the second supporting structures 24. Thus, the second supporting structures 24 extend to the through holes 250 and penetrate through the thermal insulation layer 25, and the second supporting structures 24 are connected to the thermal insulation layer 25 and seal the through holes 250. In other words, the second supporting structures 24 are located between and connected to the thermal insulation layer 25 and the electrically insulating layer 12 of the substrate 10. Thus, the thermal insulator 20 is disposed on the electrically insulating layer 12 of the substrate 10. Also, the electrically insulating layer 12 of the substrate 10, the sidewall structure 21, the second supporting structures 24, and the thermal insulation layer 25 together form a vacuum and airtight space S. The second supporting structures 24 may be formed by performing any suitable conventional method, such as spraying, coating, or chemical vapor deposition.

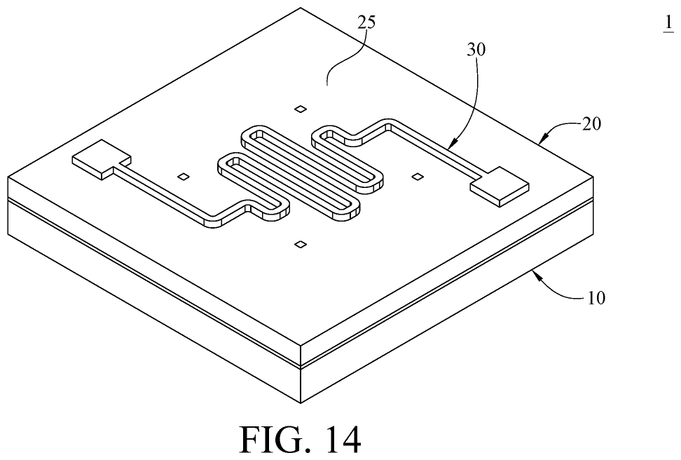

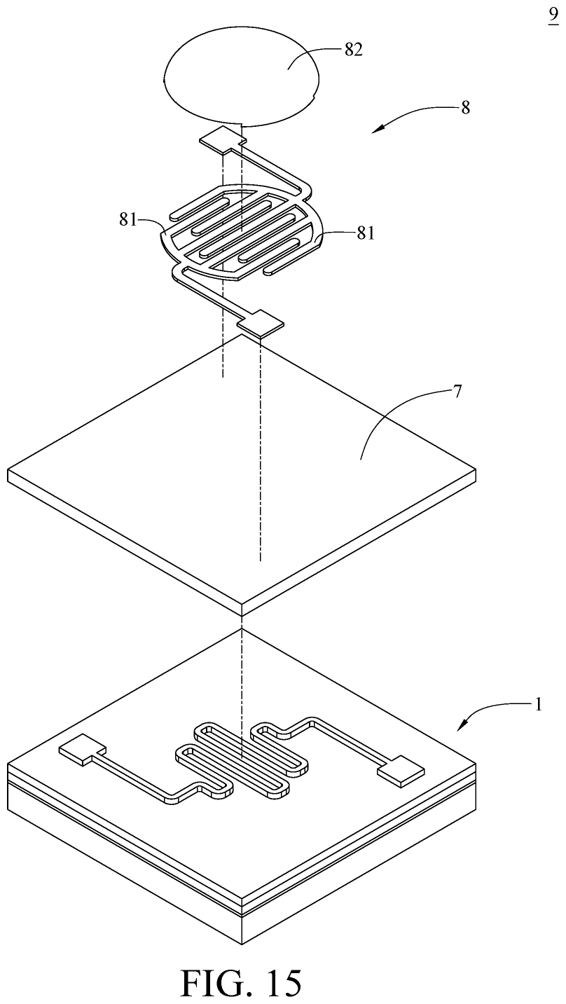

FIG. 14 is a partial perspective view of the microelectromechanical heating device in FIG. 1. Then, a heater 30 is formed on the thermal insulation layer 25 of the thermal insulator 20. By doing so, a microelectromechanical heating device 1, which has the substrate 10, the thermal insulator 20 disposed on the substrate 10, and the heater 30 disposed on the thermal insulator 20, is obtained.

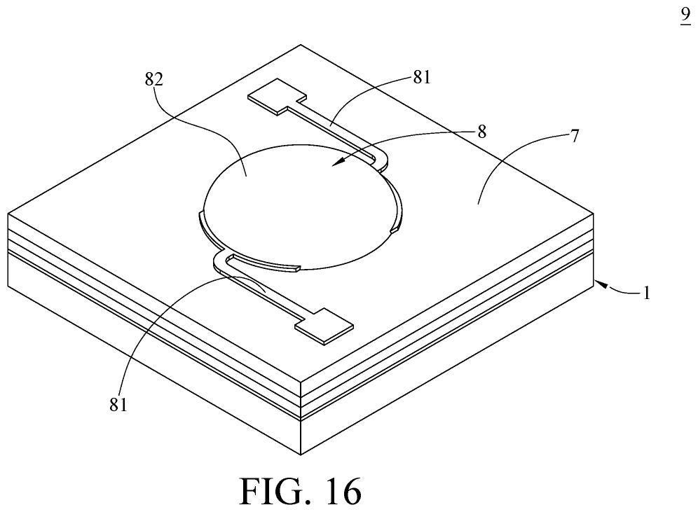

Referring to FIG. 15 and FIG. 16, where FIG. 15 is an exploded view of an application that adapts the microelectromechanical heating device in FIG. 1, and FIG. 16 is a perspective view of an application that adapts the microelectromechanical heating device in FIG. 15.

The microelectromechanical heating device shown in FIG. 1 may be applied to a gas sensor 9. An electrically insulating layer 7 is disposed on the microelectromechanical heating device 1. A gas sensing module 8 is disposed on the electrically insulating layer 7. The gas sensing module 8 includes sensing electrodes 81 and a gas sensing material 82. The sensing electrodes 81 are disposed on the electrically insulating layer 7. The gas sensing material 82 is disposed on the sensing electrodes 81 and the electrically insulating layer 7. Each of the sensing electrodes 81 may have a comb shape interlacing with the other sensing electrode 81, but the disclosure is not limited thereto. The measurement values of the gas sensor 9 can be obtained by measuring the electrical parameters of the sensing electrodes 81 after the microelectromechanical heating device 1 heats the gas sensing module 8 up to a predetermined working temperature.

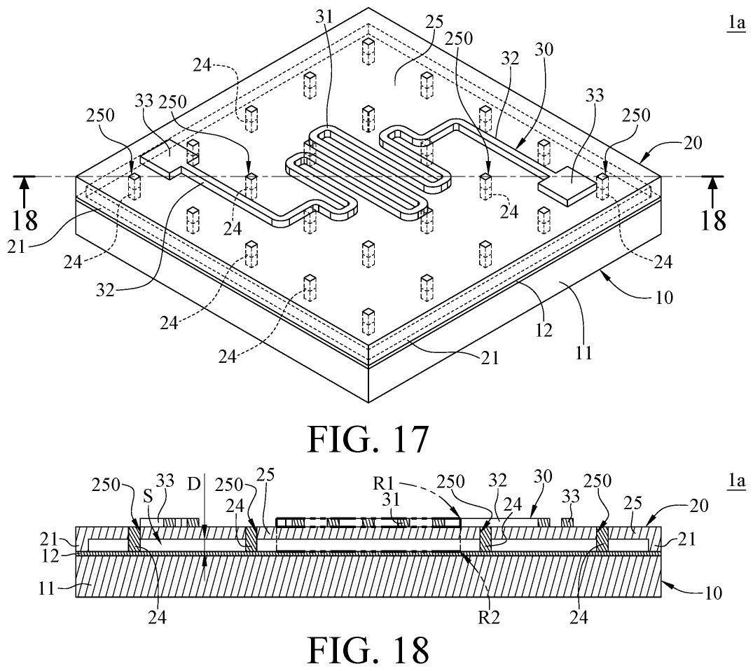

In addition, referring to FIG. 17 and FIG. 18, where FIG. 17 is a perspective view of a microelectromechanical heating device according to another embodiment of the disclosure, and FIG. 18 is a cross-sectional side view of the microelectromechanical heating device taken along line 18-18 in FIG. 17. This embodiment provides a microelectromechanical heating device 1a that is similar to the microelectromechanical heating device 1 shown in FIG. 1 and FIG. 2. Herein, similar components are numbered by the same reference numbers, and the repeated descriptions are omitted, thus only the differences between the microelectromechanical heating device 1a and the microelectromechanical heating device 1 will be provided below.

In this embodiment, the microelectromechanical heating device 1a includes a thermal insulator 20 including a sidewall structure 21, a plurality of second supporting structures 24, and a thermal insulation layer 25. As shown, the microelectromechanical heating device 1a is obtained by replacing the first supporting structures 23 of the microelectromechanical heating device 1 with the second supporting structures 24 and the through holes 250, where the second supporting structures 24 extend into the through holes 250 so as to penetrate through the thermal insulation layer 25, and the second supporting structures 24 are connected to the thermal insulation layer 25 and seal the through holes 250.

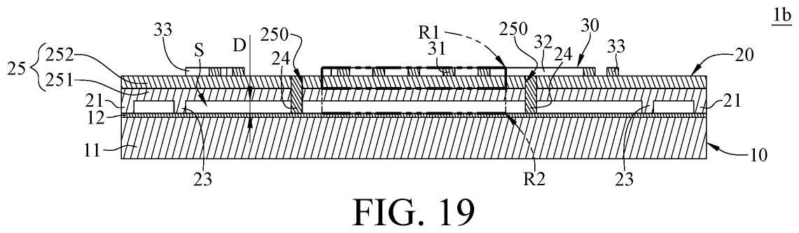

Further, referring to FIG. 19, there is shown a cross-sectional side view of a microelectromechanical heating device according to another embodiment of the disclosure. This embodiment provides a microelectromechanical heating device 1b that is similar to the microelectromechanical heating device 1 shown in FIG. 2. Herein, similar components are numbered by the same reference numbers, and the repeated descriptions are omitted, thus only the differences between the microelectromechanical heating device 1b and the microelectromechanical heating device 1 will be provided below.

In this embodiment, the microelectromechanical heating device 1b includes a thermal insulation layer 25 including a first thermal insulation layer 251 and a second thermal insulation layer 252. The first thermal insulation layer 251 is located closer to the electrically insulating layer 12 of the substrate 10 than the second thermal insulation layer 252. The first thermal insulation layer 251 is spaced apart from the electrically insulating layer 12 by a distance D of greater than or equal to 0.2 micrometers. The through holes 250 of the thermal insulation layer 25 penetrate through the first thermal insulation layer 251 and the second thermal insulation layer 252. The second supporting structures 24 extend into the through holes 250 so as to penetrate through the first thermal insulation layer 251 and the second thermal insulation layer 252, and the second supporting structures 24 are connected to the first thermal insulation layer 251 and the second thermal insulation layer 252 and seal the through holes 250.

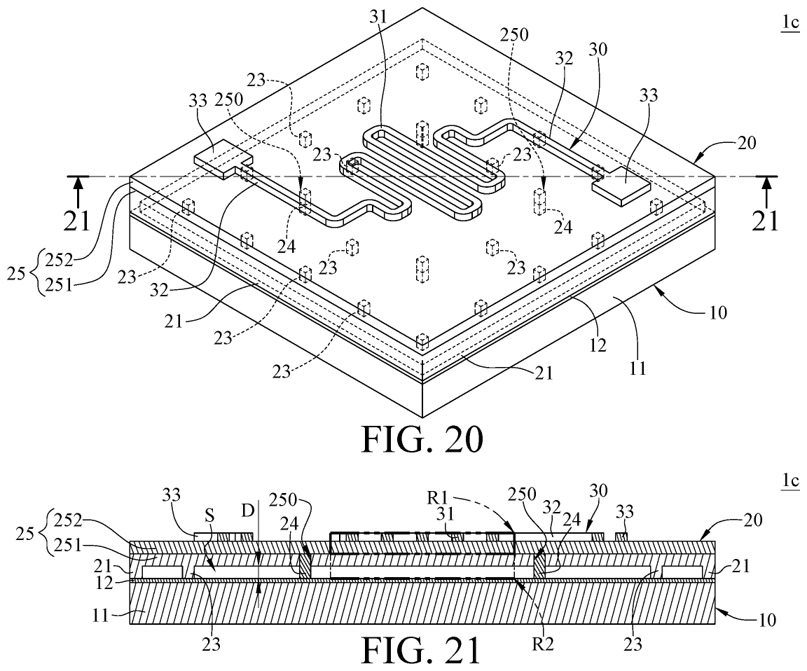

Further, referring to FIG. 20 and FIG. 21, where FIG. 20 is a perspective view of a microelectromechanical heating device according to another embodiment of the disclosure, and FIG. 21 is a cross-sectional side view of the microelectromechanical heating device taken along line 21-21 in FIG. 20. This embodiment provides a microelectromechanical heating device lc that is similar to the microelectromechanical heating device 1 shown in FIG. 1 and FIG. 2. Herein, similar components are numbered by the same reference numbers, and the repeated descriptions are omitted, thus only the differences between the microelectromechanical heating device lc and the microelectromechanical heating device 1 will be provided below.

In this embodiment, the microelectromechanical heating device lc includes a thermal insulation layer 25 including a first thermal insulation layer 251 and a second thermal insulation layer 252. The first thermal insulation layer 251 is located closer to the electrically insulating layer 12 of the substrate 10 than the second thermal insulation layer 252. The first thermal insulation layer 251 is spaced apart from the electrically insulating layer 12 by a distance D of greater than or equal to 0.2 micrometers. The through holes 250 of the thermal insulation layer 25 penetrate through the first thermal insulation layer 251. The second supporting structures 24 extend into the through holes 250 so as to penetrate through the first thermal insulation layer 251, and the second supporting structures 24 are connected to the first thermal insulation layer 251 and seal the through holes 250. The second thermal insulation layer 252 covers the first thermal insulation layer 251, the through holes 250, and the second supporting structures 24.

According to the microelectromechanical heating device as discussed in the above embodiments of the disclosure, the heater is disposed on a substrate that is spaced apart from the thermal insulation layer, such that the thermal energy generated by the heater is not easily conducted to the substrate. In addition, since the distance between the adjacent first supporting structures divided by the width of each first supporting structure is greater than or equal to 15.3, the thermal insulation layer obtains sufficient support to be spaced apart from the substrate. Also, the heat conduction area between the thermal insulation layer and the substrate is small enough to suppress the temperature increase of the substrate to be less than 50 degrees Celsius. In addition, since the space formed by the substrate and the thermal insulation layer is an airtight and vacuum space, there is no convective heat transfer between the thermal insulation layer and the substrate. As such, the heater is able to achieve the predetermined working temperature in an effective and power-saving manner, and the predetermined working temperature of the heater is easily maintained. Moreover, the substrate is not hollowed out and has no physical damage, thus the substrate may have an integrated circuit therein, therefore, the microelectromechanical heating device and the integrated circuit can be integrated into the same substrate.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A microelectromechanical heating device, comprising a substrate, a heater, and a thermal insulator, the thermal insulator comprising:
a plurality of supporting structures, disposed on the substrate; and
at least one thermal insulation layer, located above the substrate and connected to the plurality of supporting structures,
wherein the at least one thermal insulation layer is spaced apart from the substrate by a distance, and the heater is disposed on the at least one thermal insulation layer.

2. The microelectromechanical heating device according to claim 1, wherein the at least one thermal insulation layer consists of one thermal insulation layer, and the distance between the thermal insulation layer and the substrate is greater than or equal to 0.2 micrometers.

3. The microelectromechanical heating device according to claim 2, wherein each of the supporting structures is a column-shaped object, and each of the supporting structures has a central axis and a width, a distance between the central axes of two of the supporting structures adjacent to each other, divided by the width is greater than or equal to 15.3.

4. The microelectromechanical heating device according to claim 3, wherein each of the plurality of supporting structures is a square column or a circular column.

5. The microelectromechanical heating device according to claim 1, wherein the at least one thermal insulation layer comprises a plurality of thermal insulation layers, one of the plurality of thermal insulation layers that is located adjacent to the substrate is spaced apart from the substrate by a distance of greater than or equal to 0.2 micrometers.

6. The microelectromechanical heating device according to claim 5, wherein each of the supporting structures is a column-shaped object, and each of the supporting structures has a central axis and a width, a distance between the central axes of two of the supporting structures adjacent to each other, divided by the width is greater than or equal to 15.3.

7. The microelectromechanical heating device according to claim 5, wherein each of the plurality of supporting structures is a square column or a circular column.

8. The microelectromechanical heating device according to claim 1, wherein the heater has a heating portion, and the plurality of supporting structures are arranged to surround an orthogonal projection of the heating portion onto the substrate.

9. The microelectromechanical heating device according to claim 1, wherein the plurality of supporting structures are disposed between the at least one thermal insulation layer and the substrate.

10. The microelectromechanical heating device according to claim 1, wherein the plurality of supporting structures penetrate through the at least one thermal insulation layer and are connected to the at least one thermal insulation layer.

11. The microelectromechanical heating device according to claim 10, wherein the at least one thermal insulation layer comprises a first thermal insulation layer located adjacent to the substrate and a second thermal insulation layer disposed on the first thermal insulation layer, the plurality of supporting structures penetrate through the first thermal insulation layer and are connected to the first thermal insulation layer, the second thermal insulation layer covers the first thermal insulation layer and the plurality of supporting structures.

12. The microelectromechanical heating device according to claim 1, wherein the at least one thermal insulation layer consists of one thermal insulation layer, the substrate and the thermal insulation layer form an airtight space therebetween.

13. The microelectromechanical heating device according to claim 12, wherein the thermal insulation layer has a plurality of through holes, a part of the plurality of supporting structures extend to the plurality of through holes so as to seal the plurality of through holes.

14. The microelectromechanical heating device according to claim 12, wherein the airtight space is a vacuum space.

15. The microelectromechanical heating device according to claim 14, wherein the thermal insulator further comprises a sidewall structure, the airtight space is formed by the substrate, the thermal insulation layer, and the sidewall structure.

16. The microelectromechanical heating device according to claim 1, wherein the at least one thermal insulation layer comprises a plurality of thermal insulation layers, the substrate and one of the plurality of thermal insulation layers that is located adjacent to the substrate form an airtight space therebetween.

17. The microelectromechanical heating device according to claim 16, wherein each of the plurality of thermal insulation layers has a plurality of through holes, a part of the plurality of supporting structures extend to the plurality of through holes of the plurality of thermal insulation layers so as to seal the plurality of through holes.

18. The microelectromechanical heating device according to claim 16, wherein the plurality of thermal insulation layers comprise a first thermal insulation layer located adjacent to the substrate and a second thermal insulation layer disposed on the first thermal insulation layer, wherein the first thermal insulation layer has a plurality of through holes, a part of the plurality of supporting structures extend to the plurality of through holes so as to seal the plurality of through holes, the second thermal insulation layer covers the first thermal insulation layer, the plurality of supporting structures, and the plurality of through holes.

19. The microelectromechanical heating device according to claim 1, wherein the substrate comprises a non-electrically insulating layer and an electrically insulating layer which are stacked on each other, the electrically insulating layer is located closer to the thermal insulation layer than the non-electrically insulating layer.
